(19) United States
(12) Patent Application Publication
(10) Pub. No.: US 2002/0130369 A1
(43) Pub. Date: Sep. 19, 2002

(54) Semiconductor integrated circuit device with reduced cross-talk and method for fabricating same

(76) Inventors: Takayuki Iwasaki, Hitachi (JP); Yusuke Takeuchi, Hachiohji (JP); Atsuo Watanabe, Hitachiohta (JP)

Correspondence Address: DICKSTEIN SHAPIRO MORIN & OSHINSKY LLP, 2101 L STREET NW, WASHINGTON, DC, 20037-1526, US

(21) Appl. No.: 09/925,956

(22) Filed: Aug. 10, 2001

(30) Foreign Application Priority Data
Mar. 14, 2001 (JP) 2001-71373

(51) Int. Cl. H01L 29/76

(52) U.S. Cl. 257/370

(57) ABSTRACT

The present invention provides a semiconductor integrated circuit device comprising a digital circuit and an analog circuit on a common substrate wherein a substrate effect constant of the analog circuit is at least less than a substrate effect constant of the digital circuit and wherein the analog circuit further comprises a P type polysilicon gate electrode for a nMOSFET and a N type polysilicon gate electrode for a pMOSFET.

### FIELD OF THE INVENTION

The present invention relates to a semiconductor integrated circuit device with a digital circuit and an analog circuit on a common substrate, with a structure restricting cross-talk between the respective circuits via a semiconductor substrate, and a system utilizing the integrated circuit device and a fabrication process therefor.

### DISCUSSION OF THE RELATED ART

Silicon type integrated circuits have been used even in high operation frequency, for example, the GHz band. However, the silicon substrate, for example, GaAs substrate typically used in the high operation frequency of GHz band, has low insulation ability due to its low resistance. Therefore, there is relatively high possibility that an electrical signal generated in a certain element affects other elements via the substrate. Particularly, a signal generated in the digital circuit tends to flow into the analog circuit via the silicon substrate to cause degradation of analog characteristics in a semiconductor integrated circuit device, in which a digital circuit and an analog circuit are present on a common substrate. This phenomenon is referred to as substrate cross-talk which has been a serious problem in an integrated circuit, in which the digital circuit and the analog circuit are present on a common substrate. Therefore, methods to restrict the cross-talk is an important factor to improve high frequency characteristics of the semiconductor integrated circuit device.

A combined analog-digital integrated circuit according to the prior art is shown in FIG. 2. In the illustrated circuit, a digital circuit region 1 and an analog circuit region 2 are formed on a P type semiconductor substrate 3, and an nMOSFET 101 and a pMOSFET 102 are formed in the digital circuit region 1 and are isolated from each other through a local oxide film 22. This is also the case with the analog circuit region 2. Conventionally, an N type polysilicon is used as the material of the gate electrode.

As fabrication processes get more and more precise, the deterioration in short channel characteristics of a pMOSFET has become more important. Particularly, making a threshold value Vth of a pMOSFET using an N type polysilicon as a gate electrode almost equal to that of an nMOSFET, a P type element, which is reverse in conductivity to an N type well, is ion-implanted into a channel to connect between the source and drain of the pMOSFET with a P type region. At this time, since a PN junction is formed in the ion-implanted P type region and N type well region, there occurs a diffusion potential and a depletion layer extends to the surface side, pinching-off the channel, so that a depletion type is not obtained.

FIG. 8 shows a channel profile along a plane A-A′ in FIG. 7. In FIG. 7, the numeral 65 denotes a P type well, numeral 61 denotes a source, numeral 62 denotes a drain, 63 a gate oxide film, and 64 a gate electrode. FIGS. 8(a) and 8(b) illustrate an nMOSFET and a pMOSFET, respectively. As shown in FIG. 8(b), there is a PN junction in the channel depth direction. If a negative voltage is applied to the gate so that the pMOSFET turns conductive, a channel is formed in the interior of the channel. Such type of a channel is called a buried type channel. But, a channel type with a channel being formed on the surface like the nMOSFET of FIG. 8(a) is called a surface channel type.

A deterioration in characteristics as the channel becomes shorter, in the case of using an N type polysilicon as the gate electrode of a pMOSFET, is because in the case of a buried type channel a depletion layer is apt to expand to the source side and the drain-side potential drops as the drain voltage increases. When the gate length Lg is large, the decrease of the threshold value Vth caused by deterioration of the short channel characteristics is small, but as the process becomes more and more precise, while the gate length Lg is short, the decrease of the threshold value Vth becomes significant.

According to another conventional method, as a short channel countermeasure for a pMOSFET, an N type polysilicon is used as the gate electrode of an nMOSFET and a P type polysilicon is used as the gate electrode of a pMOSFET. This is called a dual gate because two kinds of gate electrode materials are used. FIGS. 9(a) and 9(b) show channel profiles for a dual gate. FIG. 9(a) is of an nMOSFET and FIG. 9(b) is of a pMOSFET. As shown, neither of FIGS. 9(a) and 9(b) there is found a PN junction, both being surface type channels. In both MOSFETs there is a division into an analog circuit region 1 and a digital circuit region 2. In this case, all of substrate terminals 8 of nMOSFETs (a substrate terminal of nMOSFET 101 in the digital circuit region and a substrate terminal 12 of nMOSFET 103 in the analog circuit region) are common through the P type semiconductor substrate 3 irrespective of whether they are analog circuit components or digital circuit components. Substrate terminals 10 and 14 of pMOSFETs 102 and 104 in the digital and analog circuit regions, respectively, are isolated from the P type semiconductor substrate through a PN junction.

Conventionally, in an integrated circuit formed on an SOI (Silicon On Insulator) substrate, as shown in FIG. 5, all of components 42, 43, 44 and 45 are isolated by the insulating film 41, so there is no interference of a digital noise. However, since substrate terminals cannot be taken out to the exterior, it is impossible to stabilize the substrate potential, thus giving rise to the problem that there occurs a substrate floating effect such as kink effect. Further, for element by element isolation it is necessary that the semiconductor layer between elements be removed by etching, thus making it impossible to shorten the element-to-element distance, which obstructs the integration of elements.

### SUMMARY OF THE INVENTION

It is an object of the present invention to realize a combined analog-digital integrated circuit of high performance wherein the noise resistance of components in an analog circuit region is improved to reduce the influence of noise propagated from a digital circuit region.

In an object of the present invention a semiconductor integrated circuit device is provided comprising a digital circuit and an analog circuit on a common substrate wherein a substrate effect constant of said analog circuit is at least less than a substrate effect constant of said digital circuit.

In another object of the present invention a semiconductor integrated circuit device is provided comprising a digital circuit and an analog circuit on a common substrate wherein a substrate effect constant of said analog circuit is at least less than a substrate effect constant of said digital circuit and wherein said analog circuit further comprises a P type polysilicon gate electrode for a nMOSFET and a N type polysilicon gate electrode for a pMOSFET.

In yet another object of the present invention a semiconductor integrated circuit device is provided comprising a digital circuit and an analog circuit on a common substrate. Further, the analog circuit has a substrate effect constant at least less than a substrate effect constant of said digital circuit and the analog circuit comprising a nMOSFET and a pMOSFET has a P type polysilicon gate electrode and a N type polysilicon gate electrode, respectively.

In yet another object of the present invention a semiconductor integrated circuit device is provided comprising a digital circuit and an analog circuit on a common substrate wherein a well impurity concentration of said analog circuit is at least less than said digital circuit.

In another object of the present invention a semiconductor integrated circuit device is provided comprising a digital circuit and an analog circuit on a common substrate wherein a gate oxide film of said analog circuit is at least thinner than said digital circuit.

In yet other objects of the present invention a processor based system utilizing the semiconductor integrated circuit of the present invention is provided as well as a manufacturing method thereof.

### BRIEF DESCRIPTION OF THE DRAWINGS

The above advantages and features of the invention will be more clearly understood from the following detailed description which is provided in connection with the accompanying drawings.

FIG. 1 is a sectional view of a semiconductor device according to the first embodiment;

FIG. 2 is a sectional view of a conventional semiconductor device;

FIG. 3 illustrates an equivalent circuit model of digital noise propagation;

FIG. 4 is a schematic diagram illustrating digital noise propagation;

FIG. 5 is a sectional view of a conventional semiconductor device;

FIG. 6 is a sectional view of a conventional semiconductor device;

FIG. 7 is a schematic sectional diagram of an nMOSFET;

FIG. 8(a) is an explanatory diagram of an impurity profile just under the channel of an N type polysilicon;

FIG. 8(b) is an explanatory diagram of an impurity profile just under the channel of a P type polysilicon;

FIG. 9(a) is an explanatory diagram of an impurity profile just under a dual gate nMOSFET channel;

FIG. 9(b) is an explanatory diagram of an impurity profile just under a dual gate pMOSFET channel;

FIG. 10 is a sectional view of a semiconductor device according to the second embodiment;

FIG. 11 is a sectional view of a semiconductor device according to the third embodiment;

FIG. 12 is an explanatory diagram showing frequency characteristics of noises generated in the semiconductor device of the first embodiment and in a conventional semiconductor device;

FIG. 13 is an explanatory diagram of a manufacturing method according to the fourth embodiment;

FIG. 14 is a block diagram of an LSI for ADSL interface according to the fifth embodiment; and

FIG. 15 is a processor based system utilizing the semiconductor device of the present invention.

### DETAILED DESCRIPTION OF THE INVENTION

Exemplary embodiment of the present invention will be described below in connection with the drawings. Other embodiments may be utilized and structural or logical changes may be made without departing from the spirit or scope of the present invention. Like items are referred to by like reference numerals throughout the drawings.

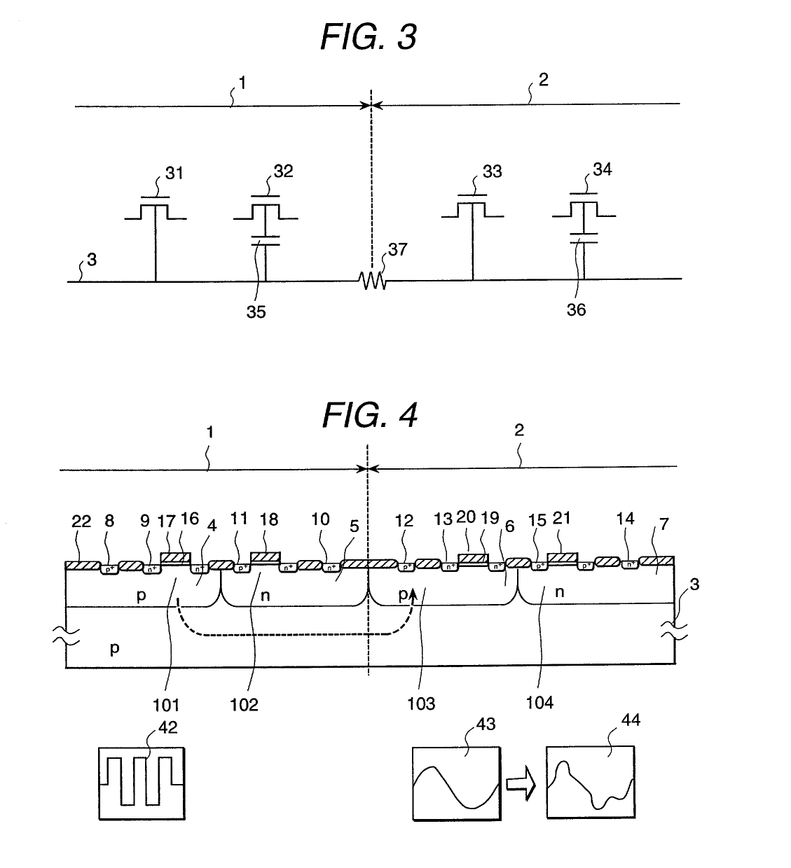

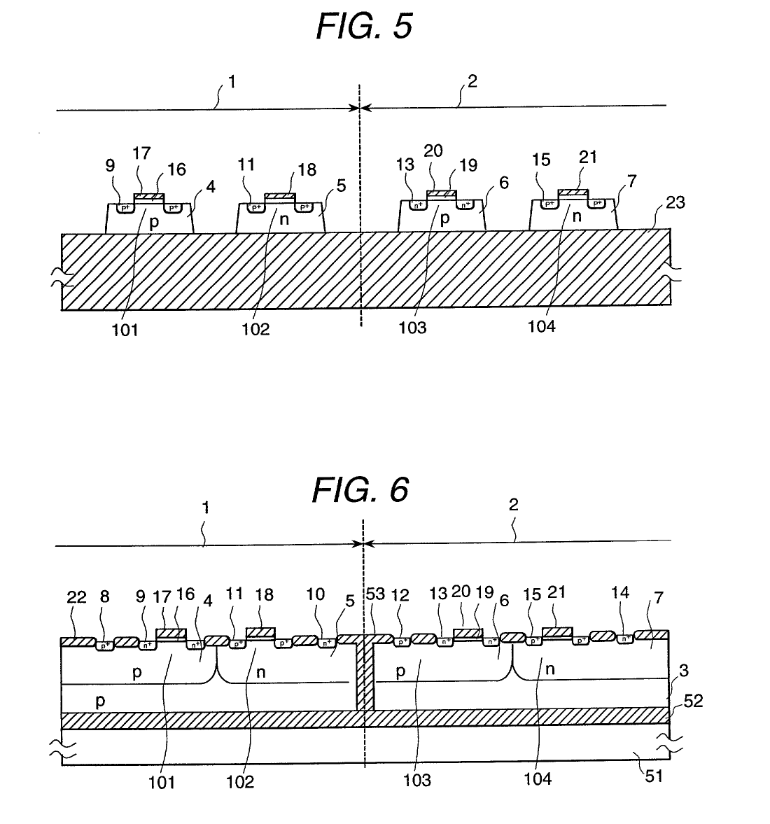

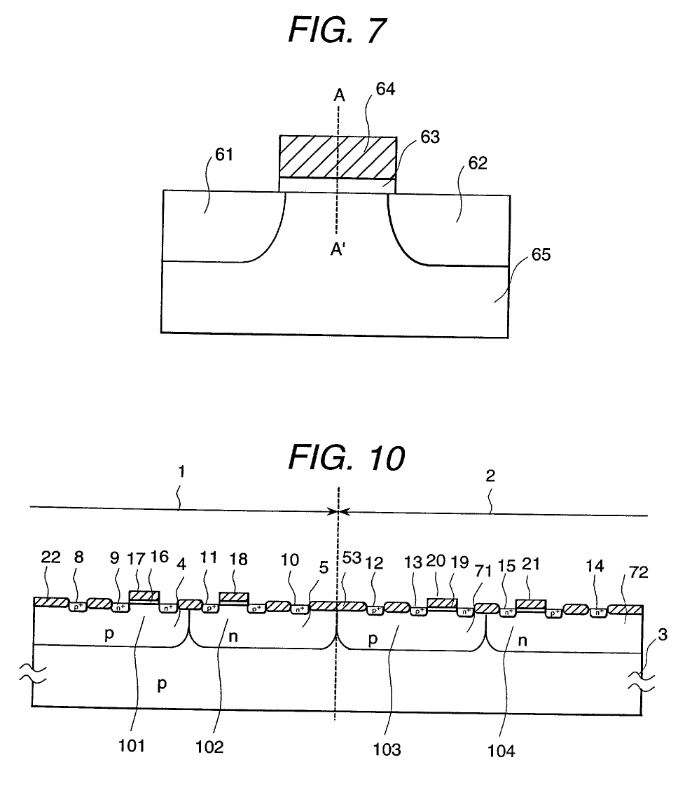

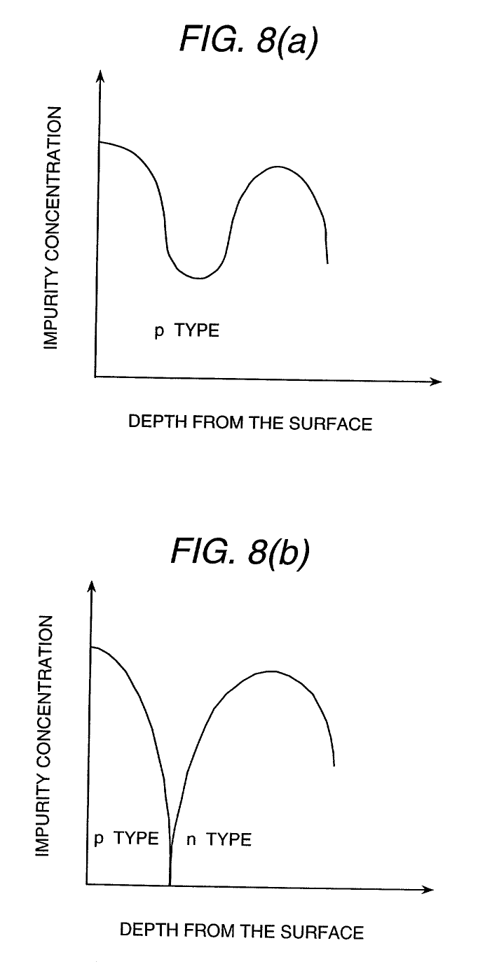

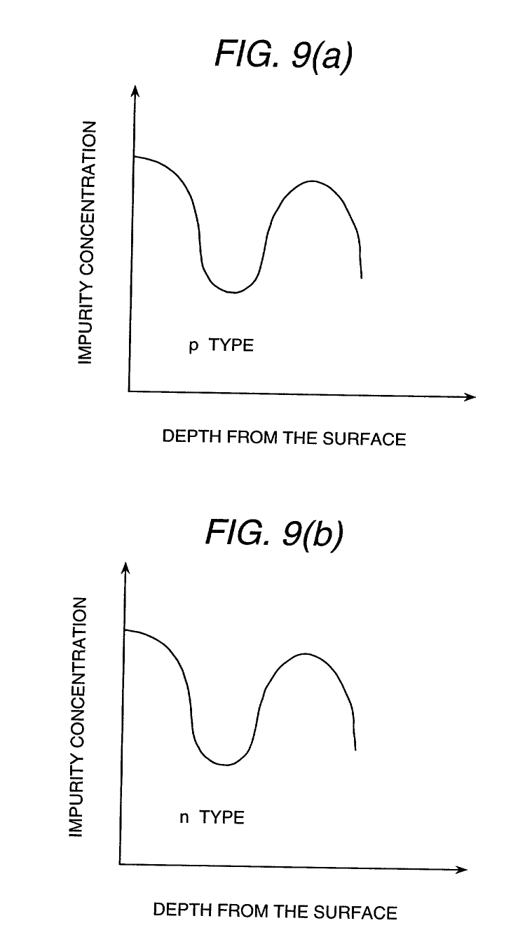

FIG. 3 shows an equivalent circuit of a combined analog-digital integrated circuit formed on the P type semiconductor substrate. All of MOSFETs are connected to the P type semiconductor substrate directly or through PN junction capacitors 35 and 36. Consequently, there arises the problem that a noise generated in the digital circuit region 1 influences the operation of the MOSFETs in the analog circuit region 2 through a P type substrate 20 and the PN junction capacitors 35 and 36.

Now, with reference to FIG. 4, the following description is provided about by what mechanism a noise 41 generated from the nMOSFET 101 in the digital circuit region enters the analog circuit region and deteriorates the characteristics of the nMOSFET 103 in the analog circuit region.

A variation quantity ΔVth of the threshold value Vth of nMOSFET can be expressed like the following equation:

ΔVth=K(√(2·ΦF+Vb)−√2·ΦF) (1)

where ΦF stands for a Fermi level of P type well and Vb stands for a substrate voltage. The equation (1) indicates that a reverse bias between the source and the substrate results in an increase of the threshold voltage Vth.

A substrate effect constant K represents to what degree the threshold value Vth is easy to change. That is, the larger the substrate effect constant K, the more greatly the threshold value Vth varies. The substrate effect constant K itself can be expressed like the following equation (2):

K=√(2·εSi·q·NA)/C0 (2)

where εSi stands for a dielectric constant of silicon, q stands for an electron charge, C0 stands for gate capacitance, and NA stands for an impurity concentration of a P type well.

Since the digital circuit region operates at a high speed, the well potential varies sharply. For example, when the voltage of a P type well 4 of the nMOSFET 101 in the digital circuit region varies, it is propagated through the P type substrate 3 and causes a change in potential of a P type well 6 of the nMOSFET in the analog circuit region. According to the equation (1), when the well potential Vb varies, the threshold value Vth varies and causes a fluctuation of drain current Ids. In the case where nMOSFET operates in a saturation region, Ids and Vth can be expressed by the following equation (3):

Ids=μ·W·C0/L·(Vgs−Vth)² (3)

where μ stands for the mobility of electron, L stands for channel length, W stands for channel width, and C0 stands for gate capacitance. According to the equation (3), the drain current Ids varies in proportion to the square of the threshold value Vth.

A description has been given above about the mechanism wherein a digital noise generated with a potential variation of the P type well 4 of the nMOSFET in the digital circuit region is propagated through the P type substrate 3 and causes the drain current Ids of the nMOSFET 103 in the analog circuit region to vary. The digital noise 41 generated in the nMOSFET in the digital circuit region 1 is propagated to the pMOSFET 104 through a junction capacitance of an N type well 7 in the analog circuit region 2 and the N type substrate 3. The higher the noise frequency, the lower the impedance of the junction capacitance, so that the propagation of the noise becomes so much marked.

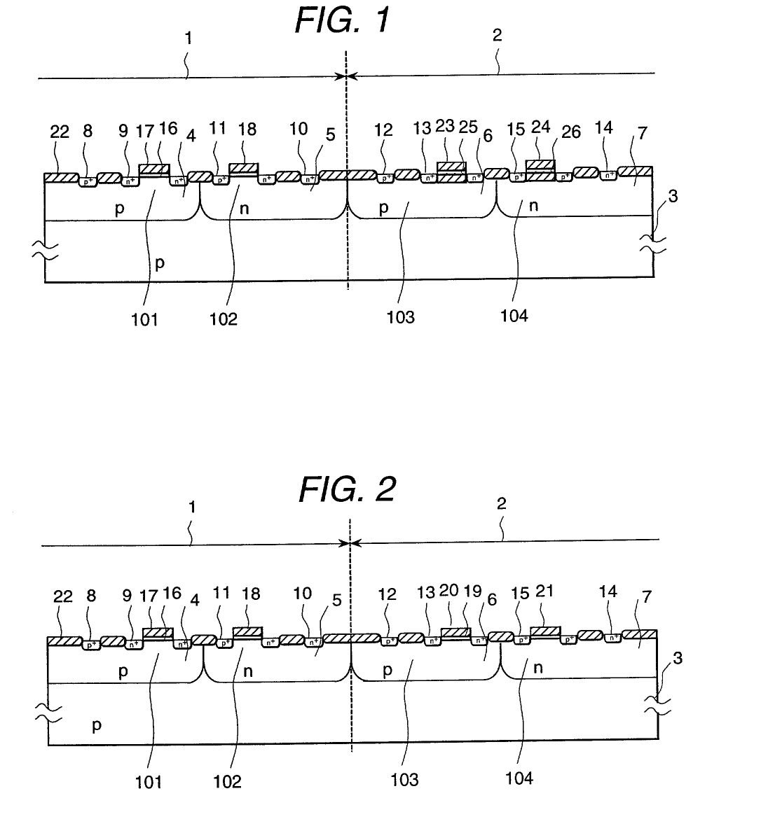

Referring now to FIG. 1, there is shown a structural sectional diagram of an embodiment of the present invention. This embodiment is different from the prior art shown in FIG. 2 in that gate electrode polysilicons are a reverse conductive type reverse to that in the prior art so as to give a buried channel type of MOSFETS in an analog circuit region. Specifically, in this embodiment, a P type polysilicon is used as a gate electrode 23 of an nMOSFET 103 in an analog circuit region 2, while an N type polysilicon is used as a gate electrode 24 of a pMOSFET 104.

Further, for decreasing the threshold value Vth, an element reverse in conductivity to a well is ion-implanted into a channel. More specifically, N and P type ion species are implanted into nMOSFET 103 and pMOSFET 104, respectively. The substrate effect constant K can be diminished for a buried type channel because a similar effect to the “decrease of well concentration NA” can be obtained by ion-implanting an element reverse in conductivity to the well into the channel.

In the case of using a buried channel type for the MOSFETs in the analog circuit region 2, the decrease of 1/f noise can also be expected in addition to the decrease of substrate effect constant. The 1/f noise indicates a noise which diminishes in inverse proportion to frequency f and becomes an issue particularly in an analog circuit which handles a low frequency. A physical model of 1/f noise generation is considered to be as follows. Traps of electrons or holes are present in the gate oxide film—substrate interface and electrons or holes passing through the channel are trapped therein, so that there occurs a fluctuation in the drain current Ids. There exists a certain time constant from the time when electrons or holes are trapped until they are released. At a high frequency, it becomes impossible for the capture and release in the traps to follow the motion of carriers, with consequent decrease of 1/f noise. The reason why the adoption of a buried channel type permits the decrease of 1/f noise is that the channel is formed in a portion more interior than the substrate surface and that therefore electrons or holes are not captured by the traps in the gate oxide film interface. Thus, the adoption of a buried type channel is problematic because of the deterioration of short channel characteristics. In the analog circuit region, however, the deterioration of short channel characteristics poses no problem since a MOSFET, small in gate length Lg, is seldom used. For example, they have the following problems: (1) Symmetry of device characterisics and (2) saturation characteristics in current-voltage characteristics are required for an analog circuit. As to “(1) symmetry of device characteristics,” the gate length Lg is made large to diminish relative variations because different gate lengths Lg of a pair of input MOSFETs induce an offset in a differential amplifier output. As to “(2) saturation characteristics in current-voltage characteristics,” the higher the dynamic resistance in a saturation region, the larger the amplification factor, assuming that MOSFETs are amplifier loads.

Although in this embodiment both nMOSFET 103 and pMOSFET 104 in the analog circuit region are a buried channel type, for a portion for which a high-speed operation is required in the analog circuit region, N and P type polysilicons are used for the gate electrodes of nMOSFET 103 and pMOSFET 104, respectively, as is the case with the digital circuit region. That is, it is not necessary for all of MOSFETS in the analog circuit region to be a buried channel type, but the surface type channel and the buried type channel are used properly according to required characteristics.

FIG. 12 compares this embodiment illustrated in FIG. 1 with the prior art illustrated in FIG. 6 with respect to noise characteristics. In both embodiments noise is less influential in a low frequency region. Thus, it is seen that a digital noise is shielded to a satisfactory extent by a trench 53 which reaches a buried insulating film 52. However, in a high frequency region, the prior art structure causes an increase of noise in comparison with the present invention. This is because the higher the frequency, the lower the impedance and the more deteriorated the digital noise shielding effect, if the trench 53 is regarded as being capacitance. But, according to the structure of this embodiment, since the device is difficult to be influenced by noise, the influence of noise can be suppressed even in a high frequency region.

Hence, the present invention provides a semiconductor integrated circuit device comprising a digital circuit and an analog circuit on a common substrate wherein a substrate effect constant of said analog circuit is at least less than a substrate effect constant of said digital circuit.

Further, the present invention provides a semiconductor integrated circuit device comprising a digital circuit and an analog circuit on a common substrate wherein a substrate effect constant of said analog circuit is at least less than a substrate effect constant of said digital circuit and wherein said analog circuit further comprises a P type polysilicon gate electrode for a nMOSFET and a N type polysilicon gate electrode for a pMOSFET.

The second embodiment will now be described with reference to FIG. 10. This embodiment is different from the prior art shown in FIG. 2 in that the impurity concentration of a P type well region 71 in the analog circuit region 2 is at least lower than that of the P type well region 4 in the digital circuit region 1. Here, the decrease in impurity concentration of the well region is effective in decreasing the substrate effect constant K. Also as to the N type well, the substrate effect constant K can be decreased by making the impurity concentration of the analog circuit region 2 lower than that of the digital circuit region 1. Although in this embodiment both nMOSFET 103 and pMOSFET 104 in the analog circuit region 2 are decreased in well concentration, the same effect as above can also be attained even by decreasing the well concentration of only one of nMOSFET and pMOSFET. Further, this embodiment may be applied to only a circuit region for which a strict noise resistance is required.

Hence, the present invention provides a semiconductor integrated circuit device comprising a digital circuit and an analog circuit on a common substrate wherein a well impurity concentration of said analog circuit is at least less than said digital circuit.

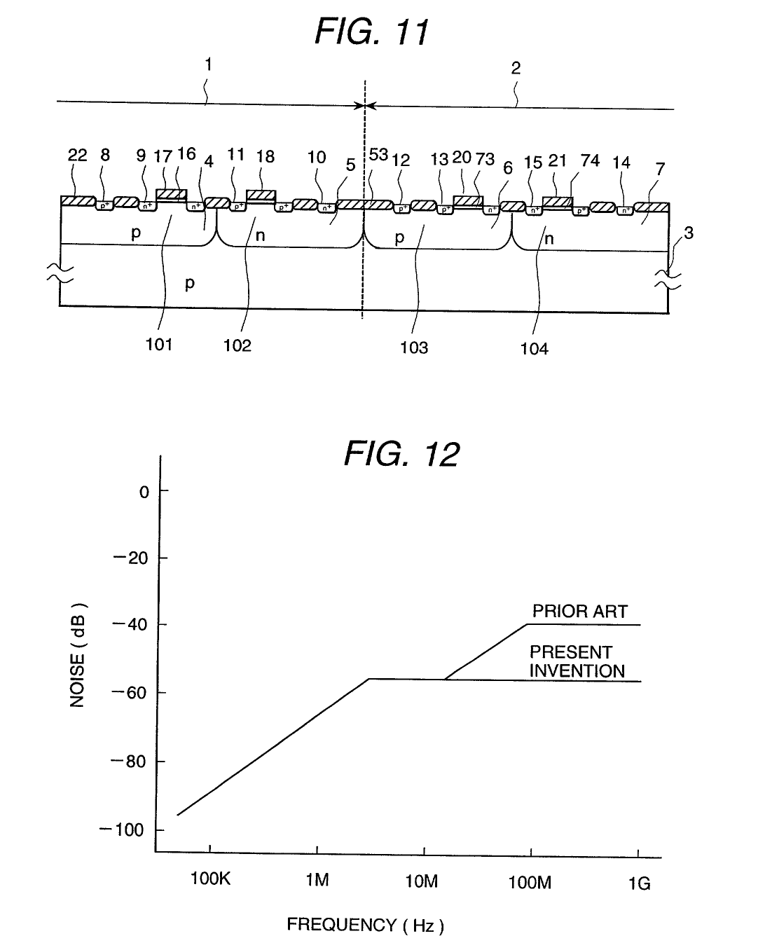

The third embodiment, which will now be described with reference to FIG. 11, is different from the prior art shown in FIG. 2 in that a gate oxide film 74 of the nMOSFET 103 in the analog circuit region 2 is at least thinner than a gate oxide film 16 of the nMOSFET in the digital circuit region 1. This increase of the gate oxide film capacitance CO is effective in decreasing the substrate effect constant K. Also, as to the gate oxide film of pMOSFET, the decrease of the substrate effect constant K can be expected by making the film thickness in the analog circuit region 2 at least smaller than that in the digital circuit region 1. Although, in this embodiment, the gate oxide film is made thin for both nMOSFET 103 and pMOSFET 104 in the analog circuit region 2, the same effect can be obtained if this is applied to only one of nMOSFET 103 or pMOSFET 104. Further, this embodiment may be applied to only a circuit region for which a strict noise resistance is required.

Hence, the present invention provides a semiconductor integrated circuit device comprising a digital circuit and an analog circuit on a common substrate wherein a gate oxide film of said analog circuit is at least thinner than said digital circuit.

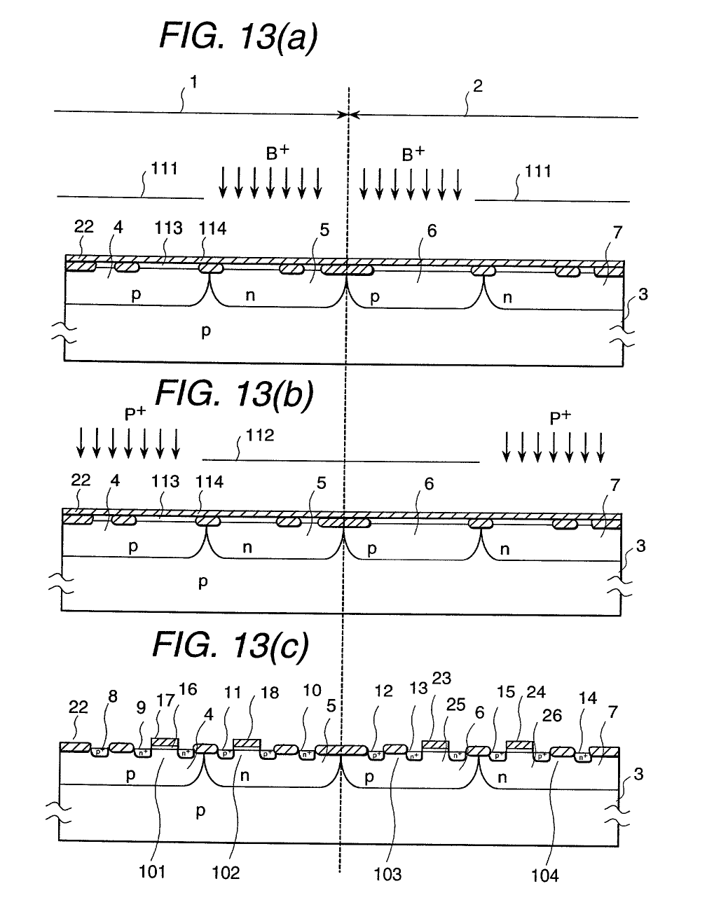

Now, with reference to FIGS. 13(a) to 13(c), the following description is provided regarding fabrication of the semiconductor device of the present invention.

As shown in FIG. 13(a), a non-doped polysilicon 114 is deposited on a substrate on which are formed a local oxide film 22, well regions in digital and analog circuit regions and a gate oxide film 113. Next, using a mask 111, a P type impurity such as boron is ion-implanted to form a P type polysilicon. Next, as shown in FIG. 13(b), an N type impurity is ion-implanted using a mask 112 to form an N type polysilicon. Then, as shown in FIG. 13(c), the polysilicon for the gate electrodes are processed to form source and drain regions and well power-supply regions. Through the above steps, an N type polysilicon is formed for gate electrodes of nMOSFET and pMOSFET in the digital and analog circuit regions, respectively. Next, a P type polysilicon is formed for gate electrodes of pMOSFET and nMOSFET in the digital and analog circuit regions, respectively.

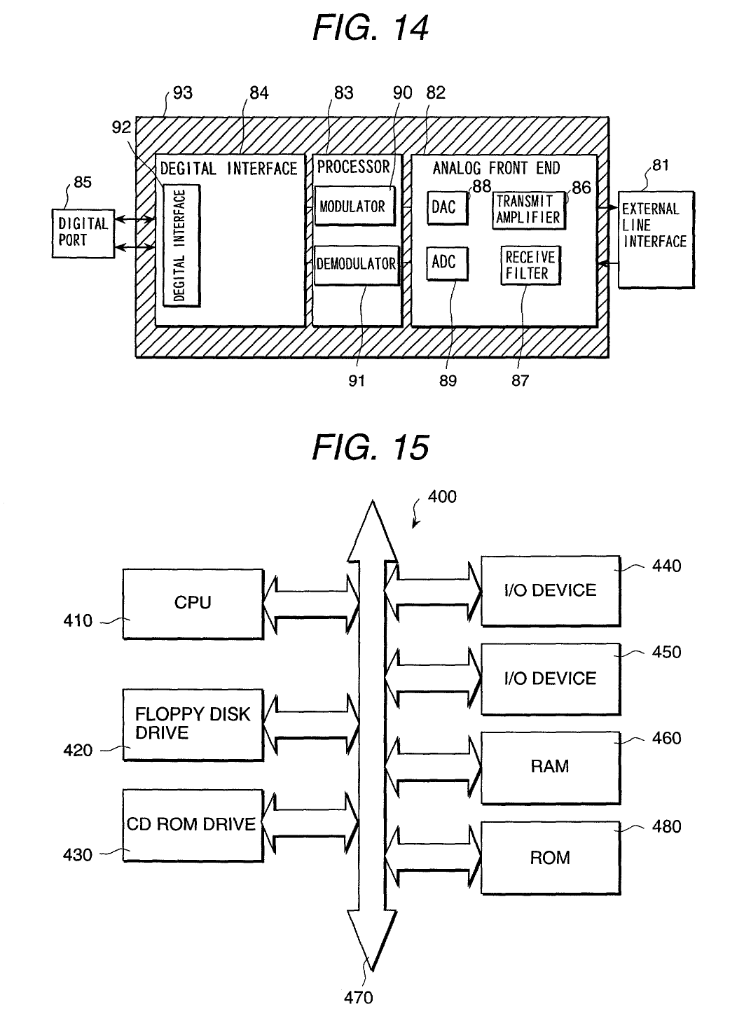

Referring now to FIG. 14, a description will be given below about an ADSL (Asymmetric Digital Subscriber Line) interface with both analog and digital circuits mounted thereon and to which the present invention can be applied. In the ADSL, there is a high frequency noise from a digital circuit region because the digital circuit operates at a high speed for realizing a high transmission speed. Analog data incoming from an external line interface 81 such as a telephone line is received by a receive filter 87, in which a required frequency is selected. An analog-digital converter 89 samples analog data and converts them into digital data. The analog-digital converter 89 is connected to a digital port 85 of, for example, a personal computer via a demodulator 91 and a digital interface.

Conversely, digital data from the digital port 85 are sent via a digital interface 92 and a modulator 90 to a digital-analog converter 88, in which they are converted to analog data. The analog data are amplified by a transmission amplifier 86 and are then sent to the external line interface 81. A division is made into a digital circuit region and an analog circuit region before and after the analog-digital converter 89 and the digital-analog converter 88. Specifically, the region close to the external line interface 81 side with respect to the analog-digital converter 89 is an analog circuit region and the region close to the digital port 85 side is a digital circuit region. Also, as to the digital-analog converter 88, the external line interface 81 side is an analog circuit region and the digital port 85 side is a digital circuit region.

The digital circuit in the ADSL operates at a high speed for transmitting a large volume of data. According to the prior art, when all the functions shown in FIG. 14 were contained onto a single chip, the analog circuit was deteriorated its characteristics under the influence of digital noise. In this embodiment, by applying the MOSFETs described in the first to third embodiments to an LSI for interface, analog circuit characteristics were improved and there was implemented an LSI of a high performance with both analog and digital circuits formed thereon.

FIG. 15 illustrates a processor system 400, including central processing unit (CPU) 410, RAM and ROM memory devices 460, 480, input/output (I/O) devices 440, 450, floppy disk drive 420 and CD ROM drive 430. All of the above components communicate with each other over one or more bus systems 470. One or more of the central processing unit (CPU) 112, is fabricated on substrate 3 as IC chips, the IC chips comprising a digital circuit and analog circuit with reduced cross-talk, as illustrated in FIG. 1 in accordance with the invention.

Although the invention has been described above in connection with exemplary embodiments, it is apparent that many modifications and substitutions can be made without departing from the spirit or scope of the invention. For instance, although reference has been made above to an ADSL as a concrete application example of the present invention, the invention is applicable not only to ADSL but also to all of combined analog-digital LSIs, including signal processing in a digital TV receiver for which both a digital circuit operating at a high speed and an analog circuit of a high performance are required on one and the same substrate. Accordingly, the invention is not to be considered as limited by the foregoing description, but is only limited by the scope of the appended claims.

What is claimed as new and desired to be protected by Letters Patent of the United States is:

1. A semiconductor integrated circuit device comprising:
a digital circuit and an analog circuit on a common substrate wherein a substrate effect constant of said analog circuit is at least less than a substrate effect constant of said digital circuit.

2. The device of claim 1 wherein said analog circuit further comprises a P type polysilicon gate electrode for a nMOSFET and a N type polysilicon gate electrode for a pMOSFET.

3. The device of claim 1 wherein said analog circuit has a buried channel structure.

4. The device of claim 1 wherein a well impurity concentration of said analog circuit is at least less than said digital circuit.

5. The device of claim 4 wherein said well impurity concentration is a P type.

6. The device of claim 4 wherein said well impurity concentration is a N type.

7. The device of claim 1 wherein a gate oxide film of said analog circuit is at least thinner than said digital circuit.

8. A semiconductor integrated circuit device comprising:
a digital circuit and an analog circuit on a common substrate wherein a substrate effect constant of said analog circuit is at least less than a substrate effect constant of said digital circuit and wherein said analog circuit further comprises a P type polysilicon gate electrode for a nMOSFET and a N type polysilicon gate electrode for a pMOSFET.

9. The device of claim 8 wherein said analog circuit has a buried channel structure.

10. The device of claim 8 wherein a well impurity concentration of said analog circuit is at least less than said digital circuit.

11. The device of claim 10 wherein said well impurity concentration is a P type.

12. The device of claim 10 wherein said well impurity concentration is a N type.

13. The device of claim 8 wherein a gate oxide film of said analog circuit is at least thinner than said digital circuit.

14. A semiconductor integrated circuit device comprising:
a digital circuit and an analog circuit on a common substrate;
said analog circuit having a substrate effect constant at least less than a substrate effect constant of said digital circuit; and
said analog circuit comprising a nMOSFET and a pMOSFET having a P type polysilicon gate electrode and a N type polysilicon gate electrode, respectively.

15. The device of claim 14 wherein said analog circuit has a buried channel structure.

16. The device of claim 14 wherein a well impurity concentration of said analog circuit is at least less than said digital circuit.

17. The device of claim 16 wherein said well impurity concentration is a P type.

18. The device of claim 16 wherein said well impurity concentration is a N type.

19. The device of claim 14 wherein a gate oxide film of said analog circuit is at least thinner than said digital circuit.

20. A semiconductor integrated circuit device comprising:
a digital circuit and an analog circuit on a common substrate wherein a well impurity concentration of said analog circuit is at least less than said digital circuit.

21. The device of claim 20 wherein said analog circuit further comprises a P type polysilicon gate electrode for a nMOSFET and a N type polysilicon gate electrode for a pMOSFET.

22. The device of claim 20 wherein said analog circuit has a buried channel structure.

23. The device of claim 20 wherein said well impurity concentration is a P type.

24. The device of claim 20 wherein said well impurity concentration is a N type.

25. The device of claim 20 wherein a gate oxide film of said analog circuit is at least thinner than said digital circuit.

26. A semiconductor integrated circuit device comprising:
a digital circuit and an analog circuit on a common substrate wherein a gate oxide film of said analog circuit is at least thinner than said digital circuit.

27. The device of claim 26 wherein said analog circuit further comprises a P type polysilicon gate electrode for a nMOSFET and a N type polysilicon gate electrode for a pMOSFET.

28. The device of claim 26 wherein said analog circuit has a buried channel structure.

29. The device of claim 26 wherein a well impurity concentration of said analog circuit is at least less than said digital circuit.

30. The device of claim 29 wherein said well impurity concentration is a P type.

31. The device of claim 29 wherein said well impurity concentration is a N type.

32. A method of fabricating a semiconductor integrated circuit device comprising the steps of:
forming a digital circuit and an analog circuit on a common substrate wherein a substrate effect constant of said analog circuit is at least less than a substrate effect constant of said digital circuit.

33. The method of claim 32 wherein said analog circuit further comprises a P type polysilicon gate electrode for a nMOSFET and a N type polysilicon gate electrode for a pMOSFET.

34. The method of claim 32 wherein said analog circuit has a buried channel structure.

35. The method of claim 32 wherein a well impurity concentration of said analog circuit is at least less than said digital circuit.

36. The method of claim 35 wherein said well impurity concentration is a P type.

37. The method of claim 35 wherein said well impurity concentration is a N type.

38. The method of claim 32 wherein a gate oxide film of said analog circuit is at least thinner than said digital circuit.

39. A method of fabricating semiconductor integrated circuit method comprising the steps of:
forming a digital circuit and an analog circuit on a common substrate wherein a substrate effect constant of said analog circuit is at least less than a substrate effect constant of said digital circuit and wherein said analog circuit further comprises a P type polysilicon gate electrode for a nMOSFET and a N type polysilicon gate electrode for a pMOSFET.

40. The method of claim 39 wherein said analog circuit has a buried channel structure.

41. The method of claim 39 wherein a well impurity concentration of said analog circuit is at least less than said digital circuit.

42. The method of claim 41 wherein said well impurity concentration is a P type.

43. The method of claim 41 wherein said well impurity concentration is a N type.

44. The method of claim 39 wherein a gate oxide film of said analog circuit is at least thinner than said digital circuit.

45. A method of fabricating semiconductor integrated circuit method comprising the steps of:
forming a digital circuit and an analog circuit on a common substrate;
said analog circuit having a substrate effect constant at least less than a substrate effect constant of said digital circuit; and
said analog circuit comprising a nMOSFET and a pMOSFET having a P type polysilicon gate electrode and a N type polysilicon gate electrode, respectively.

46. The method of claim 45 wherein said analog circuit has a buried channel structure.

47. The method of claim 45 wherein a well impurity concentration of said analog circuit is at least less than said digital circuit.

48. The method of claim 47 wherein said well impurity concentration is a P type.

49. The method of claim 47 wherein said well impurity concentration is a N type.

50. The method of claim 45 wherein a gate oxide film of said analog circuit is at least thinner than said digital circuit.

51. A method of fabricating semiconductor integrated circuit method comprising the steps of:
forming a digital circuit and an analog circuit on a common substrate wherein a well impurity concentration of said analog circuit is at least less than said digital circuit.

52. The method of claim 51 wherein said analog circuit further comprises a P type polysilicon gate electrode for a nMOSFET and a N type polysilicon gate electrode for a pMOSFET.

53. The method of claim 51 wherein said analog circuit has a buried channel structure.

54. The method of claim 51 wherein said well impurity concentration is a P type.

55. The method of claim 51 wherein said well impurity concentration is a N type.

56. The method of claim 51 wherein a gate oxide film of said analog circuit is at least thinner than said digital circuit.

57. A method of fabricating semiconductor integrated circuit method comprising the steps of:
forming a digital circuit and an analog circuit on a common substrate wherein a gate oxide film of said analog circuit is at least thinner than said digital circuit.

58. The method of claim 57 wherein said analog circuit further comprises a P type polysilicon gate electrode for a nMOSFET and a N type polysilicon gate electrode for a pMOSFET.

59. The method of claim 57 wherein said analog circuit has a buried channel structure.

60. The method of claim 57 wherein a well impurity concentration of said analog circuit is at least less than said digital circuit.

61. The method of claim 60 wherein said well impurity concentration is a P type.

62. The method of claim 60 wherein said well impurity concentration is a N type.

63. A processor based-system comprising:
a processor; and
an integrated circuit coupled to said processor, at least one of said integrated circuit and processor comprising:
a digital circuit and an analog circuit on a common substrate wherein a substrate effect constant of said analog circuit is at least less than a substrate effect constant of said digital circuit.

64. The system of claim 63 wherein said analog circuit further comprises a P type polysilicon gate electrode for a nMOSFET and a N type polysilicon gate electrode for a pMOSFET.

65. The system of claim 63 wherein said analog circuit has a buried channel structure.

66. The system of claim 63 wherein a well impurity concentration of said analog circuit is at least less than said digital circuit.

67. The system of claim 66 wherein said well impurity concentration is a P type.

68. The system of claim 66 wherein said well impurity concentration is a N type.

69. The system of claim 63 wherein a gate oxide film of said analog circuit is at least thinner than said digital circuit.

70. The system of claim 63 wherein said integrated circuit is an Asymmetric Digital Subscriber Line.

71. A processor based-system comprising:
a processor; and
an integrated circuit coupled to said processor, at least one of said integrated circuit and processor comprising:
a digital circuit and an analog circuit on a common substrate wherein a substrate effect constant of said analog circuit is at least less than a substrate effect constant of said digital circuit and wherein said analog circuit further comprises a P type polysilicon gate electrode for a nMOSFET and a N type polysilicon gate electrode for a pMOSFET.

72. The system of claim 71 wherein said analog circuit has a buried channel structure.

73. The system of claim 71 wherein a well impurity concentration of said analog circuit is at least less than said digital circuit.

74. The system of claim 73 wherein said well impurity concentration is a P type.

75. The system of claim 73 wherein said well impurity concentration is a N type.

76. The system of claim 71 wherein a gate oxide film of said analog circuit is at least thinner than said digital circuit.

77. The system of claim 71 wherein said integrated circuit is an Asymmetric Digital Subscriber Line.

78. A processor based-system comprising:
a processor; and
an integrated circuit coupled to said processor, at least one of said integrated circuit and processor comprising:
a digital circuit and an analog circuit on a common substrate;
said analog circuit having a substrate effect constant at least less than a substrate effect constant of said digital circuit; and
said analog circuit comprising a nMOSFET and a pMOSFET having a P type polysilicon gate electrode and a N type polysilicon gate electrode, respectively.

79. The system of claim 78 wherein said analog circuit has a buried channel structure.

80. The system of claim 78 wherein a well impurity concentration of said analog circuit is at least less than said digital circuit.

81. The system of claim 80 wherein said well impurity concentration is a P type.

82. The system of claim 80 wherein said well impurity concentration is a N type.

83. The system of claim 78 wherein a gate oxide film of said analog circuit is at least thinner than said digital circuit.

84. The system of claim 78 wherein a gate oxide film of said analog circuit is at least thinner than said digital circuit.

85. The system of claim 78 wherein said integrated circuit is an Asymmetric Digital Subscriber Line.

86. A processor based-system comprising:
a processor; and
an integrated circuit coupled to said processor, at least one of said integrated circuit and processor comprising:
a digital circuit and an analog circuit on a common substrate wherein a well impurity concentration of said analog circuit is at least less than said digital circuit.

87. The system of claim 86 wherein said analog circuit further comprises a P type polysilicon gate electrode for a nMOSFET and a N type polysilicon gate electrode for a pMOSFET.

88. The system of claim 86 wherein said analog circuit has a buried channel structure.

89. The system of claim 86 wherein said well impurity concentration is a P type.

90. The system of claim 86 wherein said well impurity concentration is a N type.

91. The system of claim 86 wherein a gate oxide film of said analog circuit is at least thinner than said digital circuit.

92. The system of claim 86 wherein said integrated circuit is an Asymmetric Digital Subscriber Line.

93. A processor based-system comprising:
a processor; and
an integrated circuit coupled to said processor, at least one of said integrated circuit and processor comprising:
a digital circuit and an analog circuit on a common substrate wherein a gate oxide film of said analog circuit is at least thinner than said digital circuit.

94. The system of claim 93 wherein said analog circuit further comprises a P type polysilicon gate electrode for a nMOSFET and a N type polysilicon gate electrode for a pMOSFET.

95. The system of claim 93 wherein said analog circuit has a buried channel structure.

96. The system of claim 93 wherein a well impurity concentration of said analog circuit is at least less than said digital circuit.

97. The system of claim 96 wherein said well impurity concentration is a P type.

98. The system of claim 96 wherein said well impurity concentration is a N type.

99. The system of claim 93 wherein said integrated circuit is an Asymmetric Digital Subscriber Line.

100. A method for fabricating a semiconductor device having a digital circuit and an analog circuit on a common substrate comprising the steps of:
depositing a non-doped polysilicon on said substrate;
ion-implanting a P type impurity into said non-doped polysilicon using a first mask to form a P type polysilicon;
ion-implanting an N type impurity into said non-doped polysilicon using a second mask to form an N type polysilicon; and
processing said ion-implanting polysilicon to form an N type polysilicon as a gate electrode of an nMOSFET in said digital circuit region and as a gate electrode of a pMOSFET in said analog circuit region.

101. The method of claim 100 wherein a substrate effect constant of said analog circuit is at least less than a substrate effect constant of said digital circuit.

102. The method of claim 100 wherein said analog circuit has a buried channel structure.

103. The method of claim 100 wherein a well impurity concentration of said analog circuit is at least less than said digital circuit.

104. The method of claim 103 wherein said well impurity concentration is a P type.

105. The method of claim 103 wherein said well impurity concentration is a N type.

106. The method of claim 100 wherein a gate oxide film of said analog circuit is at least thinner than said digital circuit.
